(19) United States
(12) Patent Application Publication
(10) Pub. No.: US 2025/0142928 A1
(43) Pub. Date: May 1, 2025

(54) BACK BARRIER INTEGRATION SCHEME FOR GAN DEVICES

(71) Applicant: STMicroelectronics International N.V., Geneva (CH)

(72) Inventors: Cristina TRINGALI, Augusta (IT); Alessandro CONTARINO, San Gregorio di Cantania (IT); Raffaella PEZZUTO, Milano (IT); Ferdinando IUCOLANO, Gravina di Catania (IT); Maria Eloisa CASTAGNA, Catania (IT); Aurore CONSTANT, Tours (IT)

(21) Appl. No.: 18/497,482

(22) Filed: Oct. 30, 2023

(51) Int. Cl. H01L 29/417; H01L 29/20; H01L 29/40; H01L 29/66; H01L 29/778

(52) U.S. Cl. CPC H10D 64/254; H10D 30/015; H10D 30/475; H10D 62/8503; H10D 64/01; H10D 64/111

(57) ABSTRACT

Various embodiments of the present disclosure disclose improved gallium nitride (GaN) power devices and methods of fabrication of such devices. A method for fabricating a GaN device may include providing a semiconductor base material with a first and second side. The semiconductor base material includes a GaN material, a frontside barrier layer, and a backside barrier layer. A pGaN landing is formed on a first region of the semiconductor base material and an ohmic contact is formed on a second region of the semiconductor base material. The ohmic contact includes one or more via contact landing and one or more backside barrier contacts that make direct contact with the backside barrier layer.

### TECHNOLOGICAL FIELD

Example embodiments of the present disclosure relate generally to the field of gallium nitride (GaN) devices, and in particular, to back barrier integration schemes for GaN high electron mobility transistors (HEMTs).

### BACKGROUND

Applicant has identified many technical challenges and difficulties associated with GaN devices, such as the GaN HEMTs. Through applied effort, ingenuity, and innovation, Applicant has solved problems related to the dynamic drain source resistance, as well as other performance limitations of traditional GaN HEMT structures, by developing solutions embodied in the present disclosure, which are described in detail below.

### BRIEF SUMMARY

Various embodiments described herein relate to systems, apparatuses, products, and methods for the fabrication and use of GaN devices.

In some embodiments, a method includes providing a semiconductor base material including a first side and a second side, wherein the semiconductor base material includes a gallium nitride (GaN) material, the first side includes a frontside barrier layer, and the second side includes a backside barrier layer; forming a pGaN landing on a first region of the first side of the semiconductor base material; removing a portion of the frontside barrier layer on at least one portion of a second region of the first side of the semiconductor base material to form an ohmic contact on the at least one portion of the second region; and removing one or more portions of the semiconductor base material at one or more contact positions within the at least one portion of the second region to form one or more back barrier contacts.

In some embodiments, the method further includes forming a metallic layer over the at least one portion of the second region, wherein the metallic layer directly contacts the backside barrier layer at the one or more contact positions.

In some embodiments, the metallic layer includes a titanium (Ti), an aluminum copper (AlCu), or a titanium nitride (TiN) material.

In some embodiments, the method further includes forming one or more via contact landings at one or more via positions on the metallic layer.

In some embodiments, the one or more via positions are separated from the one or more contact positions.

In some embodiments, the method includes forming a substrate layer over the metallic layer.

In some embodiments, the substrate layer is formed using a plasma enhanced chemical vapor deposition (PECVD) process.

In some embodiments, the substrate layer includes a silicon nitride (SiN) material.

In some embodiments, the forming the pGaN landing includes etching the pGAN landing on the first region of the first side of the semiconductor base material; forming, through an atomic layer deposition (ALD) process, an aluminum oxide (Al₂O₃) layer over the first region and the second region of the first side of the semiconductor base material, wherein the Al₂O₃ layer covers the pGAN landing; forming, through a plasma enhanced chemical vapor deposition (PECVD) process, a silicon oxide (SiO₂) layer over the pGaN landing; and forming a substrate layer over the first region and the second region of the first side of the semiconductor base material, wherein the substrate layer covers the SiO₂ layer.

In some embodiments, removing the portion of the frontside barrier layer on the second region further includes removing the Al₂O₃ layer, the SiO₂ layer, and the substrate layer.

In some embodiments, the one or more contact positions are based at least in part on a drain position, wherein the drain position is indicative of a location of a drain on the semiconductor base material.

In some embodiments, the one or more contact positions are separated by at least a contact distance, wherein the contact distance is based at least in part on a drain distance between the one or more contact positions and the drain position.

In some embodiments, the method includes determining the drain distance; and determining the contact distance based at least in part on the drain distance, wherein the contact distance is within a threshold of the drain distance.

In some embodiments, the method includes forming a metal gate on the pGaN landing to form a pGaN gate, wherein the metal gate includes a titanium nitride (TiN) material.

In some embodiments, the method includes forming, through a plasma enhanced chemical vapor deposition (PECVD) process, a gate contact dielectric over the pGAN gate.

In some embodiments, a gallium nitride (GaN) device includes a semiconductor base material with a first side and a second side, wherein the semiconductor base material includes a GaN material, the first side includes an aluminum gallium nitride (AlGaN) layer, and the second side includes a backside barrier layer; a pGaN landing on a first region of the first side of the semiconductor base material; an ohmic contact on a second region of the first side of the semiconductor base material; and one or more back barrier contacts at one or more contact positions within the second region.

In some embodiments, the GaN device is a GaN high electron mobility transistor (HEMT).

In some embodiments, the backside barrier layer includes a second AlGaN layer or a MgGaN layer.

In some embodiments, the GaN device includes a pGaN gate on the pGaN landing.

In some embodiments, the GaN device includes one or more via contact landings at one or more via positions within the second region, wherein the one or more via positions are separate from the one or more contact positions.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF SUMMARY OF THE DRAWINGS

Having thus described certain example embodiments of the present disclosure in general terms, reference will now be made to the accompanying drawings, which are not necessarily drawn to scale, and wherein:

FIG. 1 illustrates an example computing entity in accordance with one or more embodiments of the present disclosure;

FIGS. 2A-B illustrate example sections of a GaN device in accordance with one or more embodiments of the present disclosure;

FIG. 3 illustrates an example back barrier contact positioning scheme in accordance with one or more embodiments of the present disclosure;

FIG. 4 illustrates an example first stage of a GaN HEMT fabrication process in accordance with one or more embodiments of the present disclosure;

FIGS. 5A-B illustrate an example second stage of a GaN HEMT fabrication process in accordance with one or more embodiments of the present disclosure;

FIGS. 6A-B illustrates an example third stage of a GaN HEMT fabrication process in accordance with one or more embodiments of the present disclosure; and

FIG. 7 illustrates a flowchart of an example method for fabricating a GaN device in accordance with one or more embodiments of the present disclosure.

### DETAILED DESCRIPTION

Embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

Various example embodiments of the present disclosure are directed to improved GaN devices and systems, apparatuses, products, and methods for fabricating improved GaN devices. The present disclosure, in some examples, describes a method of fabrication for GaN heterostructures that reduce dynamic drain source resistance and Ron degradation in GaN devices, to improve upon traditional GaN devices.

Traditionally, GaN heterostructures may be used for high-power and high-frequency field effect transistors. However, they are typically required to work in a normally depletion mode, rather than an enhancement mode (normally-off). Enhancement mode devices are beneficial to guarantee safe operation and drive circuit simplification as well as reduce power expenditure. A critical issue for enhancement mode devices, especially GaN HEMT power structures, is the trade-off between Ron degradation after OFF state condition and the off-state breakdown. To obtain reasonable values of vertical leakage, it is necessary to compensate for the involuntary n-doping of GaN by means of incorporation of other elements, such iron (Fe) and carbon (C). However, the presence of these elements in GaN HEMT power structures contributes to Ron degradation and leads to significant increases in the resistance of power devices.

Some embodiments of the present disclosure describe a GaN heterostructure that decreases Ron degradation, while preventing off-state breakdown. This leads to less resistance in power devices, without degrading the devices over time. The GaN heterostructure may be used to improve any power transfer device including consumer-grade battery chargers to commercial electric vehicle chargers. Unique features of the present invention include (i) the integration of a back barrier in a GaN heterostructure design that is connected via multiple back barrier contacts and (ii) fabrication techniques for fabricating the GaN heterostructure. The GaN heterostructure design may replace traditional techniques for optimizing the trade-off between the off-state breakdown and Ron degradation, including techniques that utilize additional p-GaN regions grown over an aluminum gallium nitride (AlGaN) layer and connected to a drain. These regions may be replaced and improved upon by implementing back barrier contacts within an ohmic region of a GaN heterostructure in accordance with some of the GaN heterostructure designs of the present disclosure.

It should be readily appreciated that the embodiments of the systems, apparatus, and methods described herein may be configured in various additional and alternative manners in addition to those expressly described herein.

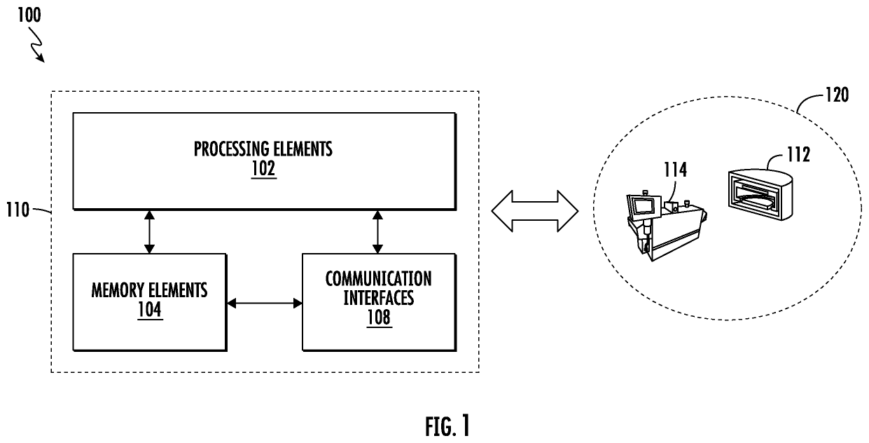

FIG. 1 illustrates an example computing system 100 in accordance with one or more embodiments of the present disclosure. In general, the terms computing system, computer, system, device, entity, and/or similar words used herein interchangeably may refer to, for example, one or more computers, computing entities, desktops, mobile phones, tablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes may be performed on data, content, information, and/or similar terms used herein interchangeably.

The computing system 100 may include a computing apparatus 110 and/or one or more computing entities 120 communicatively coupled to the computing apparatus 110 using one or more wired and/or wireless communication techniques. The computing apparatus 110 may include any computing device including, for example, one or more services, computing platforms, and/or the like, that are specially configured to perform one or more steps/operations of the one or more fabrication techniques described herein. In some embodiments, the computing apparatus 110 may include and/or be in association with one or more mobile device(s), desktop computer(s), laptop(s), server(s), cloud computing platform(s), and/or the like. In some example embodiments, the computing apparatus 110 may be configured to receive and/or provide power conversion instructions, data, and/or the like between the one or more computing entities 120 to perform one or more steps/operations of one or more fabrication techniques described herein.

In some embodiments, the computing apparatus 110 includes, is integrated with, and/or is otherwise in association with one or more computing entities 120. The one or more computing entities 120 may include one or more semiconductor fabrication devices, such as one or more etching devices 114 (e.g., ion-etching device, chemical etching devices, physical etching devices, etc.), one or more material deposition device 112 (e.g., atomic layer deposition (ALD) devices, plasma enhanced atomic layer deposition (PEALD) devices, plasma enhanced chemical vapor deposition (PECVD) device, sputter vapor deposition, thermal evaporation, arc vapor deposition, etc.), and/or the like. For example, the computing apparatus 110 may be configured to receive and/or provide one or more fabrication instructions between one or more components of the one or more computing entities 120. The computing entities 120, for example, may include and/or be associated with one or more fabrication systems configured to perform one or more fabrication operations for fabricating GaN, and/or other power devices. The one or more fabrication systems, for example, may be configured to fabricate one or more GaN HEMT power devices for use with one or more converters, inverters, power supplies, battery chargers, motor control systems, and/or the like.

The computing apparatus 110 may include, or be in communication with, one or more processing elements 102 (also referred to as processors, processing circuitry, digital circuitry, and/or similar terms used herein interchangeably) that communicate with other elements within the computing apparatus 110 via a bus, for example. As will be understood, the processing element 102 may be embodied in a number of different ways.

For example, the processing element 102 may be embodied as one or more complex programmable logic devices (CPLDs), microprocessors, multi-core processors, coprocessing entities, application-specific instruction-set processors (ASIPs), microcontrollers, and/or controllers. Further, the processing element 102 may be embodied as one or more other processing devices or circuitry. The term circuitry may refer to an entirely hardware embodiment or a combination of hardware and computer program products. Thus, the processing element 102 may be embodied as integrated circuits, application specific integrated circuits (ASICs), field programmable gate arrays (FPGAs), programmable logic arrays (PLAs), hardware accelerators, digital circuitry, and/or the like.

As will therefore be understood, the processing element 102 may be configured for a particular use or configured to execute instructions stored in volatile or non-volatile media or otherwise accessible to the processing element 102. As such, whether configured by hardware or computer program products, or by a combination thereof, the processing element 102 may be capable of performing steps or operations according to embodiments of the present disclosure when configured accordingly.

In one embodiment, the computing apparatus 110 may further include, or be in communication with, one or more memory elements 104. The one or more memory elements 104 may include non-volatile and/or volatile media. The memory elements 104, for example, may include non-volatile media (also referred to as non-volatile storage, memory, memory storage, memory circuitry and/or similar terms used herein interchangeably). In one embodiment, the non-volatile storage or memory may include one or more non-volatile storage or memory media, including, but not limited to, hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like.

As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In addition, or alternatively, the memory elements 104 may include volatile memory. For example, the computing apparatus 110 may further include, or be in communication with, volatile media (also referred to as volatile storage memory, memory storage, memory circuitry and/or similar terms used herein interchangeably). In one embodiment, the volatile storage or memory may also include one or more volatile storage or memory media, including, but not limited to, RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like.

As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing element 102. Thus, the databases, database instances, database management systems, data, applications, programs, program modules, scripts, source code, object code, byte code, compiled code, interpreted code, machine code, executable instructions, and/or the like may be used to control certain aspects of the operation of the computing apparatus 110 with the assistance of the processing element 102 and operating system.

As indicated, in one embodiment, the computing apparatus 110 may also include one or more communication interfaces 108 for communicating with various computing entities, including computing entities 120, such as by communicating data, content, information, and/or similar terms used herein interchangeably that may be transmitted, received, operated on, processed, displayed, stored, and/or the like. The one or more communication interfaces 108, for example, may include one or more wired peripherals (e.g., fiber interfaces, ethernet ports, and/or the like), antenna, transmitters, receivers, digital to analog converters (DAC), analog to digital converters (ADC), modulators, demodulators, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing apparatus 110 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.9 (Wi-Fi), Wi-Fi Direct, 802.16 (WiMAX), ultra-wideband (UWB), infrared (IR) protocols, NFC protocols such as NFC-A, NFC-B, NFC-F, Wibrec, Bluetooth protocols, wireless universal serial bus (USB) protocols, and/or any other wireless protocol.

The computing apparatus 110 may include input/output circuitry for communicating with one or more users. The input/output circuitry, for example, may include one or more user interfaces for providing and/or receiving information from one or more users of the computing apparatus 110. The input/output interfaces may include one or more tactile interfaces (e.g., keypads, touch screens, etc.), one or more audio interfaces (e.g., microphones, speakers, etc.), visual interfaces (e.g., display devices, etc.), and/or the like. The input/output circuitry may be configured to receive user input through one or more of the user interfaces from a user of computing apparatus 110 and provide data to a user through one or more of the user interfaces.

Example embodiments of the present disclosure describe an improved GaN heterostructures that may be fabricated using improved fabrication techniques. The improved fabrication techniques modify traditional GaN heterostructures by adding back barrier contacts to reduce Ron degradation and resistance of GaN devices among other benefits described herein.

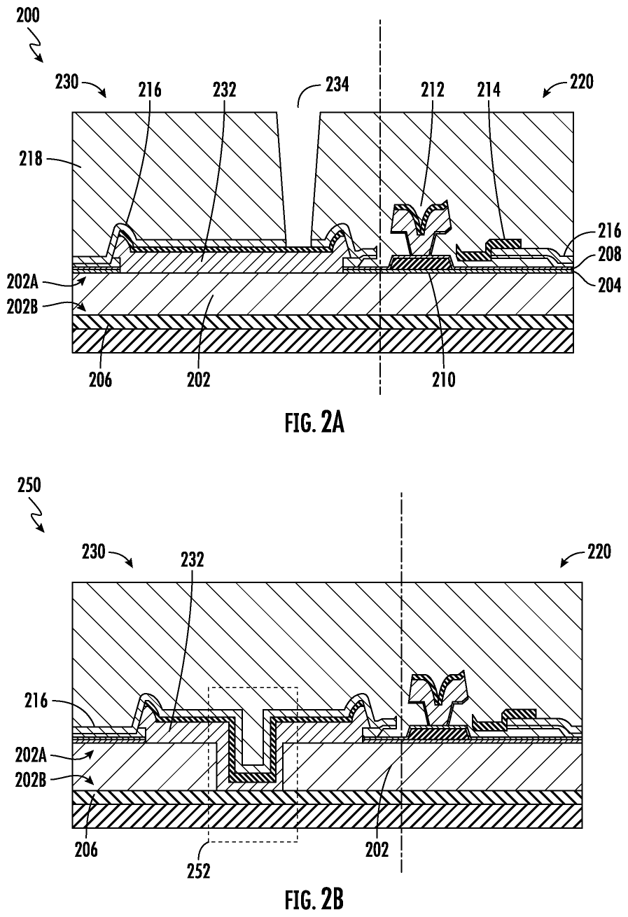

FIGS. 2A-B illustrate example sections of a GaN device in accordance with one or more embodiments of the present disclosure. The GaN device, for example, may include a GaN high electron mobility transistor (HEMT). In a first section 200, the GaN device may include a Via contact 324. In a second section 250, the GaN device may include a back barrier contact 252.

In some embodiments, with reference to FIG. 2A, the GaN device includes a semiconductor base material 202 with a first side 202A and a second side 202B. The first side 202A may include a frontside barrier layer 204. The frontside barrier layer 204 may include a layer of conductive material, such as a first AlGaN layer. The second side 202B may include backside barrier layer 206. The backside barrier layer 206 may include another layer of conductive material, such as a second AlGaN layer. In addition, or alternatively, the backside barrier layer 206 may include a magnesium GaN (MgGaN) layer.

In some examples, the semiconductor base material 202 may include a GaN material that is disposed between the frontside barrier layer 204 and the backside barrier layer 206. For instance, the GaN material may be disposed between two AlGaN layers (e.g., on the first side 202A and second side 202B, respectively). In some examples, the GaN device may include an insulating layer 208 that is disposed over the frontside barrier layer 204. The insulating layer 208 may include any insulating material. In some embodiments, the insulating layer 208 includes an aluminum oxide (Al₂O₃) layer.

In some embodiments, the GaN device includes a first region 220 and a second region 230 on the first side 202A of the semiconductor base material 202. The second region 230 may be adjacent to the first region 220. In some examples, the first region 220 may include a gate region that is positioned between a drain region and a source region of the GaN device. In some examples, the second region 230 may include an ohmic source region. In some embodiments, the GaN device includes a drain region (not depicted) separated from a source region (e.g., the second region 230) by a gate region (e.g., the first region 220).

In some embodiments, the first region 220 includes a pGaN structure. The pGaN structure includes pGaN landing 210 on the first region 220 of the first side 202A of the semiconductor base material 202. The pGaN landing 210 may include a conductive material that is directly in contact with the frontside barrier layer 204 (e.g., the first AlGaN layer). In some examples, the pGaN structure may include a pGaN gate 212 disposed on the pGaN landing 210. In some examples, the pGaN gate 212 may include a metal gate. In some examples, the metal gate may be separated from the pGaN landing 210 by a portion of the insulating layer 208. The metal gate may include any metallic material, such as titanium nitride (TiN), and/or the like.

In some embodiments, the first region 220 includes a field plate structure 214 and/or one or more substrate materials. The field plate structure 214, for example, may include a metallic structure placed at an edge of the pGaN gate 212 to reduce the peak electric field at the gate edge. This may increase the breakdown voltage, weaken the strong field electron effect, suppress the current collapse, and increase the output power of the GaN device. The field plate structure 214 may include any metallic material, such as titanium nitride (TiN), and/or the like. In some examples, the field plate structure 214 may be the same material as the pGaN gate 212.

In some embodiments, the one or more substrate materials may include a substrate layer 216 and an insulating pad 218. The substrate layer 216 may be disposed over one or more metallic layers in the first region 220 and the second region 230 of the first side 202A of the semiconductor base material 202. As described herein, on the first region 220, the substrate layer 216 may be initially disposed over the pGaN landing 210 and removed to form the pGaN gate 212. The substrate layer 216 may include any insulating material. As one example, the substrate layer 216 may include a silicon nitride (SiN) material. The insulating pad 218 may include one or more portions of the same and/or different insulating material. For instance, the insulating pad 218 may include a silicon oxide (SiO₂) material.

In some embodiments, the second region 230 includes an ohmic structure. The ohmic structure includes an ohmic contact 232 on the second region 230 of the first side 202A of the semiconductor base material 202. In some examples, the ohmic contact 232 may be disposed in direct contact with the semiconductor base material 202. For example, the ohmic contact 232 may include a metallic layer that is formed on the second region 230 on the first side 202A of the semiconductor base material 202. The metallic layer, for example, may include a titanium (Ti), aluminum copper (AlCu), a titanium nitride (TiN), and/or any other metallic material. In some examples, the substrate layer 216 may be formed at least partially over the ohmic contact 232.

In some embodiments, in the first section 200 of the GaN device, the second region 230 includes a plurality of via contact landings 234. Each via contact landing 234 may include an opening in the insulating pad 218 and the substrate layer 216 to allow access to the ohmic contact 232.

With reference to FIG. 2B, in the second section 250 of the GaN device, the second region 230 may include one or more back barrier contacts 252. A back barrier contact 252 may include a hole in the semiconductor base material 202 that allows the ohmic contact 232 to directly contact the backside barrier layer 206. For example, a back barrier contact 252 may be fabricated by removing one or more portions of the semiconductor base material 202 below one or more contact positions within the second region 230 to form one or more holes within the semiconductor base material 202. The back barrier contact 252 may be formed by depositing a metallic layer within the one or more holes, such that the metallic layer directly contacts the backside barrier layer 206. In this manner, the ohmic contact 232 may include a continuous metallic layer that is disposed at least partially on the first side 202A of the semiconductor base material 202 and at least partially on the second side 202B of the semiconductor base material 202.

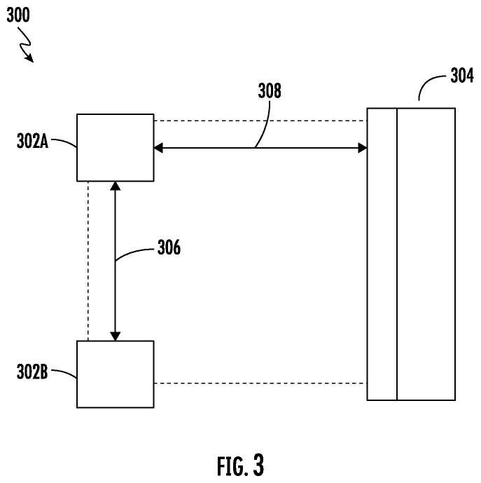

In some embodiments, the second region 230 may include a plurality of back barrier contacts 252 that are placed at one or more contact positions. In some examples, the contact positions may be strategically placed to reduce impact to resistance from one or more via contact dimensions. For example, a back barrier contact positioning scheme will now be further described with reference to FIG. 3.

FIG. 3 illustrates an example back barrier contact positioning scheme 300 in accordance with one or more embodiments of the present disclosure. The back barrier contact positioning scheme 300 may include determining one or more contact positions 302A-B for one or more back barrier contacts of the GaN device. In some examples, the one or more contact positions 302A-B may be based at least in part on a drain position 304. For instance, the GaN device may include a drain electrode that is positioned across from the second region of the semiconductor base material. For example, the drain electrode may be positioned in a drain region that is separated from the second region by a first region that includes pGaN gate.

In some embodiments, the drain position 304 is indicative of a location of the drain on the semiconductor base material. The location, for example, may be a relative location that is relative to the second region of the semiconductor base material. In some examples, the one or more contact positions 302A-B may be separated by at least a contact distance 306. The contact distance may be based at least in part on a drain distance 308 between the one or more contact positions 302A-B and the drain position 304. For example, the back barrier contact positioning scheme 300 may include determining the drain distance 308 and then determining the contact distance 306 based at least in part on the drain distance 308. In some examples, the contact distance 306 may be within a threshold of the drain distance 308. For example, the contact distance 306 (Lcc) may be approximate to the drain distance 308 (lcd) to optimize (e.g., lower) p-GaN resistance. P-GaN resistance, for example, may be expressed as:

$$\frac{\sqrt{{LCD}^{2} + {( \frac{LCC}{2} )}^{2} - LCD}}{LCD}$$

In some examples, the contact distance 306 (Lcc) may be set to equal the drain distance 308 (lcd), such that:

$$\frac{\sqrt{1 + \frac{1}{4} - 1}}{1}$$

which is approximately 12% and not expected to significantly impact the operation of a buried p-GaN layer. For instance, in some structures the contact distance 306 (Lcc) may be fixed at 1.5 μm and the drain distance 308 (lcd) may be fixed at 3.35 μm.

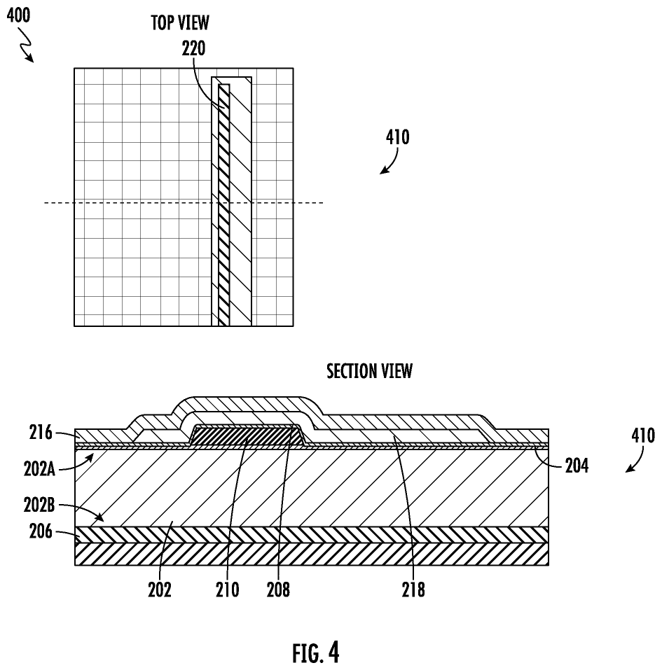

In some examples, the contact positions 302A-B may be leveraged to generate a GaN heterostructure with a plurality of back barrier contacts for optimizing performance of GaN HEMT devices. The GaN heterostructure may be fabricated over a fabrication process that includes one or more fabrication stages. A first fabrication stage will now be discussed in more detail with reference to FIG. 4.

FIG. 4 illustrates an example first stage 400 of a GaN HEMT fabrication process in accordance with one or more embodiments of the present disclosure. The first stage 400 is depicted using a top view 410 and a sectional view 420 of a GaN device. During the first stage 400, the first region 220 on the first side 202A of the semiconductor base material 202 is initially fabricated. For instance, the first stage 400 includes providing a semiconductor base material 202. The semiconductor base material 202 includes a first side 202A (e.g., a front side) and a second side 202B (e.g., a back side). As described herein, the semiconductor base material 202 may include GaN material.

In some embodiments, one or more barrier layers may be grown and/or deposited on the semiconductor base material 202. For example, a frontside barrier layer 204 may be grown and/or deposited on the surface of the first side 202A of the semiconductor base material 202. In this way, the first side 202A may include a frontside barrier layer 204. In some examples, the frontside barrier layer 204 may include an AlGaN layer. In addition, or alternatively, a backside barrier layer 206 may be grown and/or deposited on the surface of the second side 202B of the semiconductor base material 202. In this way, the second side 202B may include a backside barrier layer 206. In some examples, the backside barrier layer 206 may include the same material as the frontside barrier layer 204. For instance, the backside barrier layer 206 may include a second AlGaN layer. In addition, or alternatively, the backside barrier layer 206 may include a different material, such as a MgGaN material.

In some embodiments, the pGaN landing 210 is formed on the first region 220 of the first side 202A of the semiconductor base material 202. For instance, the pGaN landing 210 may be etched (e.g., using a resist strip and/or tetraethyl orthosilicate (TEOS) removal) on the first region 220 of the first side 202A of the semiconductor base material 202. For instance, the pGaN landing 210 may be etched into the frontside barrier layer 204 (e.g., the first AlGaN layer, etc.).

In some embodiments, an insulating layer 208 is formed over the frontside barrier layer 204 and the pGaN landing 210. As described herein, the insulating layer 208 may include any insulating material, such as an Al₂O₃ layer. In some examples, the insulating layer 208 may be formed through an atomic layer deposition (ALD) process (e.g., H₂O-based 300 degree Celsius, etc.) to deposit Al₂O₃ layer over the first region 220 and the second region (not depicted) of the first side 202A of the semiconductor base material 202. In some examples, the insulating layer 208 may be deposited after the formation of the pGaN landing 210 such that the insulating layer 208 covers the pGaN landing 210.

In some embodiments, a portion of an insulating pad 218 is formed over the first region 220. For instance, the insulating pad 218 may be formed through a PECVD process to deposit an SiO₂ layer over at least a portion of the first region 220 of the first side 202A of the semiconductor base material 202. The insulating pad 218, for example, may be formed over the pGaN landing 210 and at least a portion of the insulating layer 208. In some examples, the insulating pad 218 may be applied by a sealing deposition PECVD to deposit a SiH₄-based SiO₂. In some embodiments, the pGaN landing 210 may thereafter be sealed on the insulating layer 208.

In some embodiments, a substrate layer 216 is formed over the first region 220 and/or the second region (not depicted) of the first side 202A of the semiconductor base material 202. The substrate layer 216 may cover the insulating pad 218 (e.g., SiO₂ layer) and/or the insulating layer 208. As described herein, the substrate layer 216 may include a SiN material. In some examples, the substrate layer 216 may be deposited using a PECVD process. In some examples, the substrate layer 216 may be deposited after the formation of the pGaN landing 210 such that the substrate layer 216 covers the pGaN landing 210.

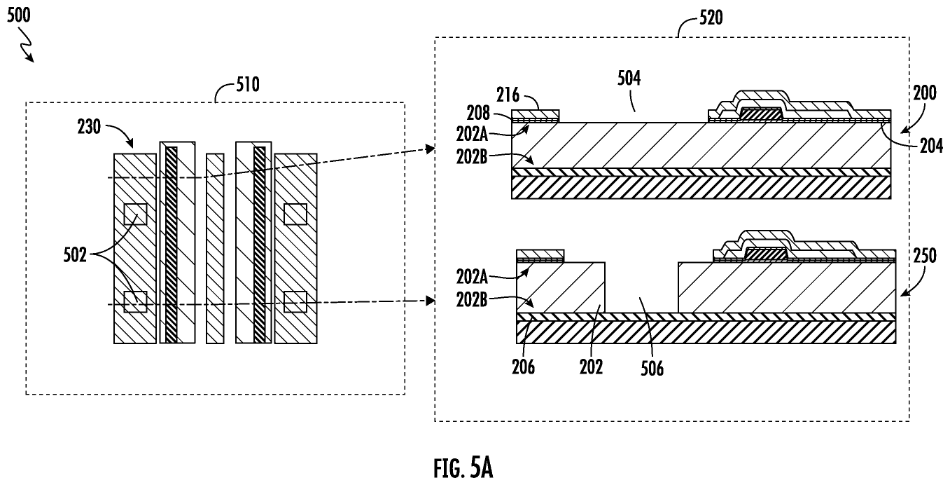

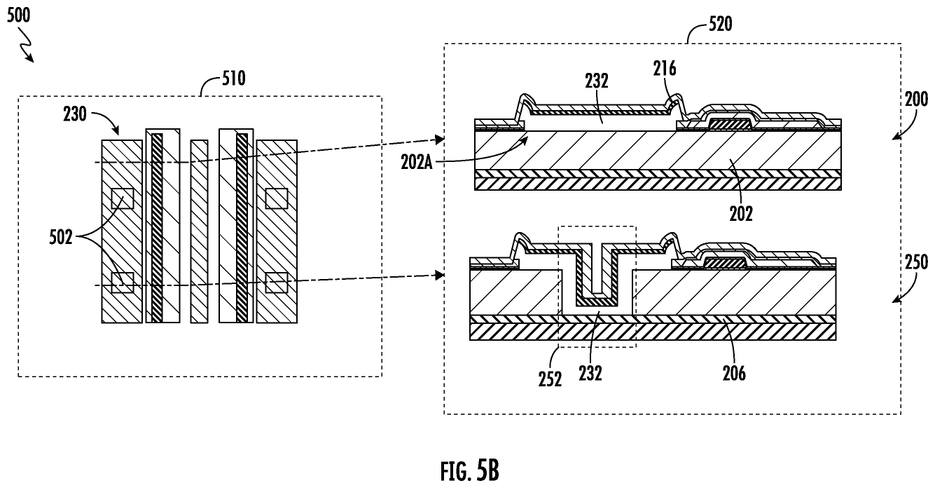

Turning to FIGS. 5A-B, FIGS. 5A-B illustrate an example second stage 500 of a GaN HEMT fabrication process in accordance with one or more embodiments of the present disclosure. The second stage 500 is depicted using a top view 510 and two sectional views 520 of a GaN device. The two sectional views 520 illustrate one or more fabrication operations on a first section 200 and a second section 250 of the GaN device. As described herein, the first section 200 may correspond to a section of the GaN device that includes one or more via landings, whereas the second section 250 may include one or more base barrier contacts. In some examples, the second section may correspond to one or more contact positions 502, as described herein.

During the second stage 500, the second region 230 on the first side 202A of the semiconductor base material 202 is initially fabricated. For instance, the second stage 500 includes removing a first portion 504 of the frontside barrier layer 204 on at least a portion of a second region 230 of the first side 202A of the semiconductor base material 202 to form an ohmic contact on at least a portion of the second region 230. For example, a first portion 504 may be removed from the substrate layer 216, the insulating layer 208, and the frontside barrier layer 204 to expose a surface of the first side 202A of the semiconductor base material 202. By way of example, the first portion 504 may be removed by removing a portion of the Al₂O₃ layer, the SiO₂ layer, and the substrate layer 216 that corresponds to a contact position 502. In some examples, the first portion 504 may be removed by etching (e.g., using a resist strip and/or polymer removal etching techniques) an ohmic contact landing on the semiconductor base material 202.

In some embodiments, in the second section 250, one or more portions 506 of the semiconductor base material 202 are further removed to form one or more back barrier contact. For example, one or more portions 506 of the semiconductor base material 202 may be removed that are below the one or more contact positions 502. The back barrier contact may be formed by etching the ohmic contact landing (e.g., using a resist strip and/or polymer removal etching techniques) to expose the backside barrier layer 206.

Turning to FIG. 5B, the second stage 500 may include forming a metallic layer within the etched surfaces. For example, the second stage 500 may include forming a metallic layer over at least a portion of the second region 230. In the first section 200, the metallic layer may form an ohmic contact 232 that directly contacts the surface of the first side 202A of the semiconductor base material 202. In the second section 250, the metallic layer may form an ohmic contact 232 that directly contacts the backside barrier layer 206 through the semiconductor base material 202. For example, in the second section 250, the metallic layer may directly contact the backside barrier layer 206 at the one or more contact positions 502. As described herein, the metallic layer may include a Ti, AlCu, TiN, and/or any other material suitable for an ohmic contact. In some examples, the ohmic contact 232 may be deposited using one or more deposition techniques, such as those described herein.

In some embodiments, the second stage 500 includes forming a substrate layer 216 over the metallic layer. The substrate layer 216 may be formed, for example, using a PECVD process to deposit a SiN layer (and/or similar material thereof) over the ohmic contact 232. For example, at least a portion of the substrate layer 216 may be formed after the formation of the ohmic contact 232, such that the substrate layer 216 covers the ohmic contact 232. In some embodiments, the ohmic contact 232 may be annealed through an ohmic annealing process (e.g., thermal anneal, laser-based annealing, etc.).

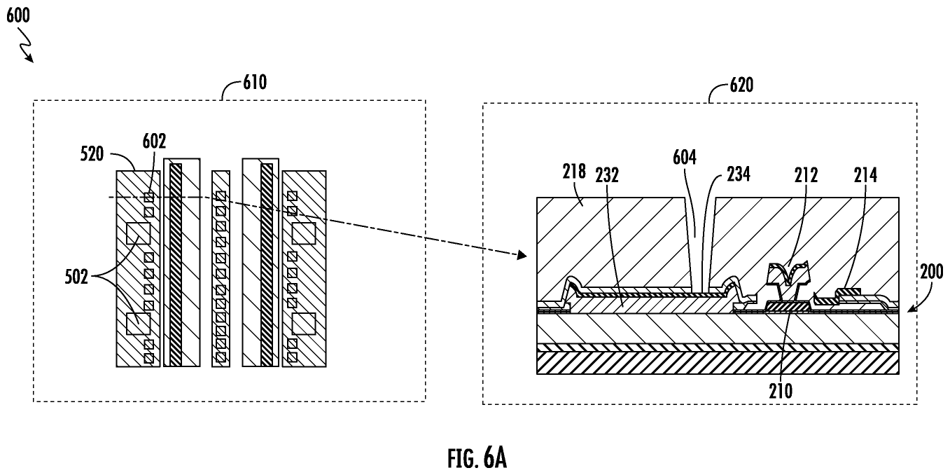

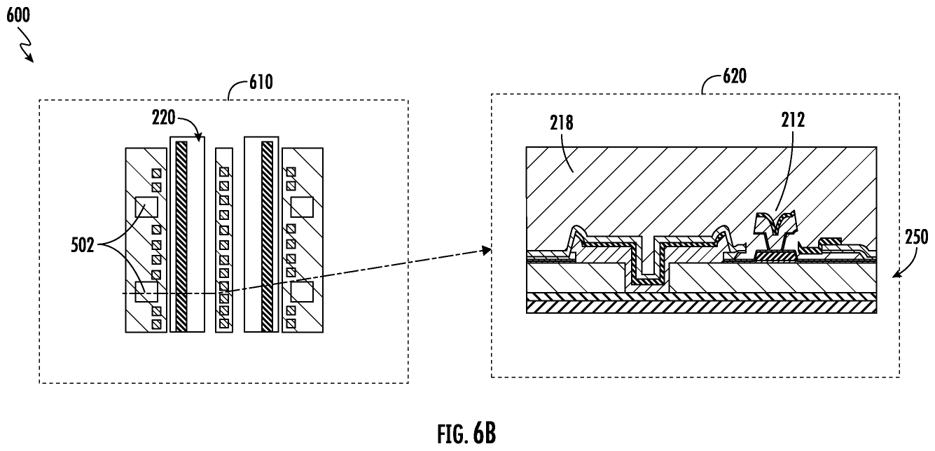

Turning to FIGS. 6A-B. FIGS. 6A-B illustrate an example third stage 600 of a GaN HEMT fabrication process in accordance with one or more embodiments of the present disclosure. The third stage 600 is depicted using a top view 610 and two sectional views 620A-B of a GaN device. A first sectional view 620A illustrates one or more fabrication operations on a first section 200 of the GaN device. A second sectional view 620B illustrates one or more fabrication operations on a second section 250 of the GaN device. As described herein, the first section 200 may correspond to a section of the GaN device that includes one or more via landings, whereas the second section 250 may include one or more base barrier contacts. In some examples, the second section 250 may correspond to one or more contact positions 502, as described herein.

In some embodiments, the third stage 600 includes forming a metal gate on the pGaN landing 210 to form a pGaN gate 212. As described herein, the metal gate may include a titanium nitride (TiN) material, and/or the like. In some examples, the third stage 600 may include forming, through a PECVD process, a gate contact dielectric over the pGaN gate 212. For example, an SiN etch landing may be formed (e.g., using resist strip and/or polymer removal techniques) on a portion of the insulating pad 218 (e.g., the SiO₂ material). The field plate structure 214 may be formed (e.g., using resist strip and/or polymer removal techniques) by depositing a metal layer, such as a TiN material, at an edge of the pGaN landing 210. A gate contact dielectric may be deposited, for example, using one or more PECVD and TEOS techniques. The gate contact and gate metal may be defined (e.g., using resist strip and polymer removal, etc.) to form the pGaN gate 212.

In some embodiments, the third stage 600 includes forming one or more via contact landings 234 at one or more via positions 602 on the ohmic contact 232. As described herein, the one or more via positions 602 may be separated from the one or more contact positions 502. In some examples, an inter-metal dielectric may be formed by depositing a dielectric using PECVD TEOS and chemical-mechanical planarization (CMP). A via contact landing 234 may be etched on the ohmic contact 232 (e.g., using resist strip and/or polymer removal, etc.).

In some embodiments, the pGaN device is finalized by forming W plugs and metal deposition and definition, forming inter-metal dielectric layers by depositing a dielectric using PECVD TEOS and CMP, defining multiple vias, and finally forming the insulating pad 218 (e.g., through passivation deposition) and removing a pad opening 604 for the vias.

Turning to FIG. 6B, the one or more of the same operations may be performed in the second section 250 to form the pGaN gate 212 across each section of the first region 220 of the GaN device.

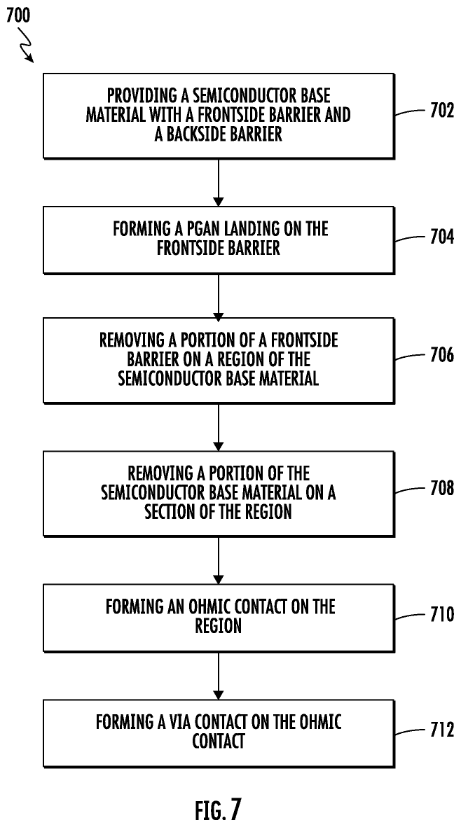

FIG. 7 illustrates a flowchart of an example method 700 for fabricating a GaN device in accordance with one or more embodiments of the present disclosure. The flowchart depicts fabrication techniques for fabricating improved GaN devices that overcome various performance limitations of traditional GaN devices. The techniques may be implemented by one or more computing devices, entities, and/or systems described herein. For example, via the various steps/operations of the method 700, a computing device, such as the computing apparatus 110 described herein, may implement the techniques (e.g., via one or more control instructions to one or more computing entities 120) to overcome the various limitations with traditional GaN devices by reducing Ron degradation, without increasing source to drain resistance.

FIG. 7 illustrates an example method 700 for explanatory purposes. Although the example method 700 depicts a particular sequence of steps/operations, the sequence may be altered without departing from the scope of the present disclosure. For example, some of the steps/operations depicted may be performed in parallel or in a different sequence that does not materially impact the function of the method 700. In other examples, different components of an example device or system that implements the method 700 may perform functions at substantially the same time or in a specific sequence.

According to some examples, the method 700 includes, at step/operation 702, providing a semiconductor base material. For example, the method 700 may include providing a semiconductor base material with a frontside barrier and a backside barrier. For example, the method 700 may include providing a semiconductor base material that includes a first side and a second side. The semiconductor base material may include a GaN material. The first side may include a frontside barrier layer. The second side may include a backside barrier layer.

According to some examples, the method 700 includes, at step/operation 704, forming a pGaN landing on the frontside barrier. For example, the method 700 may include forming the pGaN landing on a first region of the first side of the semiconductor base material. For example, the method 700 may include etching the pGAN landing on a first region of the first side of the semiconductor base material. The method 700 may include forming, through an ALD process, an Al₂O₃ layer over the first region and the second region of the first side of the semiconductor base material. The Al₂O₃ layer may cover the pGAN landing. The method 700 may include forming, through a PECVD process, a SiO₂ layer over the pGaN landing. The method may include forming a substrate layer over the first region and the second region of the first side of the semiconductor base material. The substrate layer may cover the SiO₂ layer.

In some examples, the method 700 may include forming a metal gate on the pGaN landing to form a pGaN gate. The metal gate may include a TiN material. In some examples, the method 700 may include forming, through a PECVD process, a gate contact dielectric over the pGAN gate.

According to some examples, the method 700 includes, at step/operation 706, removing a portion of the frontside barrier. For example, the method 700 may include removing the portion of the frontside barrier on at least one portion of a second region of the first side of the semiconductor base material to form an ohmic contact on the at least one portion of the second region. In some examples, removing the frontside barrier may include removing the Al₂O₃ layer, the SiO₂ layer, and/or the substrate layer.

According to some examples, the method 700 includes, at step/operation 708, removing a portion of the semiconductor base material. For example, the method 700 may include removing one or more portions of the semiconductor base material at one or more contact positions within the at least one portion of the second region to form one or more back barrier contacts. In some examples, the one or more contact positions may be based at least in part on a drain position. For example, the drain position may be indicative of a location of a drain on the semiconductor base material. In some examples, the one or more contact positions may be separated by at least a contact distance. The contact distance, for example, may be based at least in part on a drain distance between the one or more contact positions and the drain position.

By way of example, the method 700 may include determining the drain distance and determining the contact distance based at least in part on the drain distance. The contact distance may be within a threshold of the drain distance.

According to some examples, the method 700 includes, at step/operation 710, forming an ohmic contact on the first region. For example, the method 700 may include forming a continuous ohmic contact across the first region of the semiconductor base material. For example, the method 700 may include forming a metallic layer over the at least one portion of the second region. The metallic layer may directly contact the backside barrier layer at the one or more contact positions. In some examples, the metallic layer may include at least one of a titanium (Ti), an aluminum copper (AlCu), and/or a titanium nitride (TiN) material.

In some examples, the method 700 may include forming a substrate layer over the metallic layer. The substrate layer may be formed using a PECVD process. The substrate layer may include an SiN material.

According to some examples, the method 700 includes, at step/operation 712, forming a via contact landing on the ohmic contact. For example, the method 700 may include forming one or more via contact landings at one or more via positions on the metallic layer. In some examples, the one or more via positions are separated from the one or more contact positions.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to GaN power devices and techniques for fabricating GaN power devices, however, one skilled in the art may recognize that such principles may be applied to any semiconductor device. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

While this detailed description has set forth some embodiments of the present disclosure, the appended claims cover other embodiments of the present disclosure which differ from the described embodiments according to various modifications and improvements. For example, the appended claims may cover any form of semiconductor fabrication.

Within the appended claims, unless the specific term “means for” or “step for” is used within a given claim

1. A method comprising:
providing a semiconductor base material comprising a first side and a second side, wherein the semiconductor base material comprises a gallium nitride (GaN) material, the first side comprises a frontside barrier layer, and the second side comprises a backside barrier layer;
forming a pGaN landing on a first region of the first side of the semiconductor base material;
removing a portion of the frontside barrier layer on at least one portion of a second region of the first side of the semiconductor base material to form an ohmic contact on the at least one portion of the second region; and
removing one or more portions of the semiconductor base material at one or more contact positions within the at least one portion of the second region to form one or more back barrier contacts.

2. The method of claim 1 further comprising forming a metallic layer over the at least one portion of the second region, wherein the metallic layer directly contacts the backside barrier layer at the one or more contact positions.

3. The method of claim 2, wherein the metallic layer comprises a titanium (Ti), an aluminum copper (AlCu), or a titanium nitride (TiN) material.

4. The method of claim 2 further comprising forming one or more via contact landings at one or more via positions on the metallic layer.

5. The method of claim 4, wherein the one or more via positions are separated from the one or more contact positions.

6. The method of claim 2 further comprising forming a substrate layer over the metallic layer.

7. The method of claim 6, wherein the substrate layer is formed using a plasma enhanced chemical vapor deposition (PECVD) process.

8. The method of claim 6, wherein the substrate layer comprises a silicon nitride (SiN) material.

9. The method of claim 1, wherein forming the pGaN landing comprises:
etching the pGAN landing on the first region of the first side of the semiconductor base material;
forming, through an atomic layer deposition (ALD) process, an aluminum oxide (Al₂O₃) layer over the first region and the second region of the first side of the semiconductor base material, wherein the Al₂O₃ layer covers the pGAN landing;
forming, through a plasma enhanced chemical vapor deposition (PECVD) process, a silicon oxide (SiO₂) layer over the pGaN landing; and
forming a substrate layer over the first region and the second region of the first side of the semiconductor base material, wherein the substrate layer covers the SiO₂ layer.

10. The method of claim 9, wherein removing the portion of the frontside barrier layer on the second region further comprises removing the Al₂O₃ layer, the SiO₂ layer, and the substrate layer.

11. The method of claim 1, wherein the one or more contact positions are based at least in part on a drain position, wherein the drain position is indicative of a location of a drain on the semiconductor base material.

12. The method of claim 11, wherein the one or more contact positions are separated by at least a contact distance, wherein the contact distance is based at least in part on a drain distance between the one or more contact positions and the drain position.

13. The method of claim 12 further comprising:
determining the drain distance; and
determining the contact distance based at least in part on the drain distance, wherein the contact distance is within a threshold of the drain distance.

14. The method of claim 1, further comprising forming a metal gate on the pGaN landing to form a pGaN gate, wherein the metal gate comprises a titanium nitride (TiN) material.

15. The method of claim 14, forming, through a plasma enhanced chemical vapor deposition (PECVD) process, a gate contact dielectric over the pGAN gate.

16. A gallium nitride (GaN) device, comprising:
a semiconductor base material with a first side and a second side, wherein the semiconductor base material comprises a GaN material, the first side comprises an aluminum gallium nitride (AlGaN) layer, and the second side comprises a backside barrier layer;
a pGaN landing on a first region of the first side of the semiconductor base material;
an ohmic contact on a second region of the first side of the semiconductor base material; and
one or more back barrier contacts at one or more contact positions within the second region.

17. The GaN device of claim 16, wherein the GaN device is a GaN high electron mobility transistor (HEMT).

18. The GaN device of claim 16, wherein the backside barrier layer comprises a second AlGaN layer or an MgGaN layer.

19. The GaN device of claim 16, further comprising a pGaN gate on the pGaN landing.

20. The GaN device of claim 16, further comprising one or more via contact landings at one or more via positions within the second region, wherein the one or more via positions are separate from the one or more contact positions.
